(19) United States
(12) Patent Application Publication
(10) Pub. No.: US 2026/0130209 A1
(43) Pub. Date: May 7, 2026

(54) SEMICONDUCTOR DEVICE AND METHOD FOR MANUFACTURING THE SAME

(71) Applicant: Taiwan Semiconductor Manufacturing Company, Ltd., Hsinchu (TW)

(72) Inventors: Yi-Huan Liao, Hsinchu (TW); Po-Yuan Cheng, New Taipei City (TW); Chih-Hao Chen, Taipei City (TW); Pu Wang, Hsinchu City (TW); Li-Hui Cheng, New Taipei City (TW)

(73) Assignee: Taiwan Semiconductor Manufacturing Company, Ltd., Hsinchu (TW)

(21) Appl. No.: 18/935,690

(22) Filed: Nov. 4, 2024

(51) Int. Cl. H01L 23/367; H01L 21/48; H01L 23/00; H01L 23/10; H01L 23/31; H01L 23/433; H01L 25/16

(52) U.S. Cl. CPC H10W 40/22; H10W 40/77; H10W 70/02; H10W 74/131; H10W 76/60; H10W 90/00; H10W 74/15; H10W 90/724; H10W 90/734

(57) ABSTRACT

A semiconductor device including a substrate, a semiconductor package, a thermal conductive bonding layer and a lid is provided. The semiconductor package is disposed on the substrate. The thermal conductive bonding layer is disposed on the semiconductor package. The lid is attached to the semiconductor package via the thermal conductive bonding layer. The lid has a first cavity and a second cavity connected to the first cavity. The semiconductor package is located in the first cavity, and the thermal conductive bonding layer is partially disposed in the second cavity. The second cavity has a first portion and a second portion joined with the first portion and narrower than the first portion, the second portion is located between the first portion and the first cavity, and the thermal conductive bonding layer is formed in the second portion. A method for manufacturing a semiconductor device is also provided.

### BACKGROUND

A typical problem with miniaturization of semiconductor devices is heat dissipation during operation. A prolonged exposure of a die by operating at excessive temperatures may decrease the reliability and lifetime of the die. This problem may become severe if the die generates a lot of heat during operation. As such, improvements to heat dissipation are still needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a semiconductor device in accordance with some embodiments of the present disclosure.

FIG. 2 illustrates a cross-sectional view of a semiconductor device in accordance with some embodiments of the present disclosure.

FIG. 3 illustrates an enlarged partial cross-sectional view of a semiconductor device in accordance with some embodiments of the present disclosure.

FIG. 4 illustrates an enlarged partial cross-sectional view of a semiconductor device in accordance with some embodiments of the present disclosure.

FIG. 5 illustrates an enlarged partial cross-sectional view of a semiconductor device in accordance with some embodiments of the present disclosure.

FIG. 6 illustrates an enlarged partial cross-sectional view of a semiconductor device in accordance with some embodiments of the present disclosure.

FIG. 7 illustrates a cross-sectional view of a semiconductor device in accordance with some embodiments of the present disclosure.

FIG. 8 illustrates a flow chart of a method for manufacturing a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, it will be understood that when an element is referred to as being “connected to” or “coupled to” another element, it may be directly connected to or coupled to the other element, or one or more intervening elements may be present. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Thermal interface materials (TIMs) are materials inserted between two components in order to enhance the thermal coupling between them. For example, thermal interface materials can be inserted between heat-producing devices (e.g., integrated circuits) and heat-dissipating devices (e.g., heat sinks) to enhance the thermal dissipation performance. However, many factors in the manufacturing process, such as volume change of the thermal interface material layer caused by significant temperature change in the post reflow process (e.g., a ball mount process), poor outgassing during the post reflow process, inappropriate volume selection of the thermal interface material, etc., may lead to poor coverage of the thermal interface material layer. The poor coverage of the thermal interface material layer results in increased contact thermal resistance and/or reduced thermal dissipation performance. In addition, the stress generated at the interface between the heat-dissipating device (e.g., a lid) and the thermal interface material layer due to CTE (coefficient of thermal expansion) mismatch during the temperature variation processes (e.g., a thermal cycle testing process) can easily lead to cracks at the interface, which also results in increased contact thermal resistance and reduced thermal dissipation performance.

In the present disclosure, a lid with a first cavity as well as a second cavity is provided to achieve better coverage of the thermal conductive bonding layer (or the thermal interface material layer) or to reduce the number of voids generated in the thermal conductive bonding layer located between the heat-producing devices (e.g., a semiconductor die) and the heat-dissipating devices (e.g., the lid). In some embodiments, the second cavity has a neck portion (second portion) that is narrower than a recess portion (first portion) of the second cavity to secure the thermal conductive bonding layer with the lid, thereby improving the connection/bonding between the thermal conductive bonding layer and the lid or reducing cracks generated at the interface between the lid and the thermal conductive bonding layer. In some embodiments, the second cavity is disposed corresponding to the encapsulant of the semiconductor package instead of the semiconductor die of the semiconductor package (e.g., an orthogonal projection of the second cavity on the semiconductor package is located outside the semiconductor die and located in the encapsulant) to maintain the thermal dissipation performance (such as thermal conduction efficiency) of the heat-producing regions.

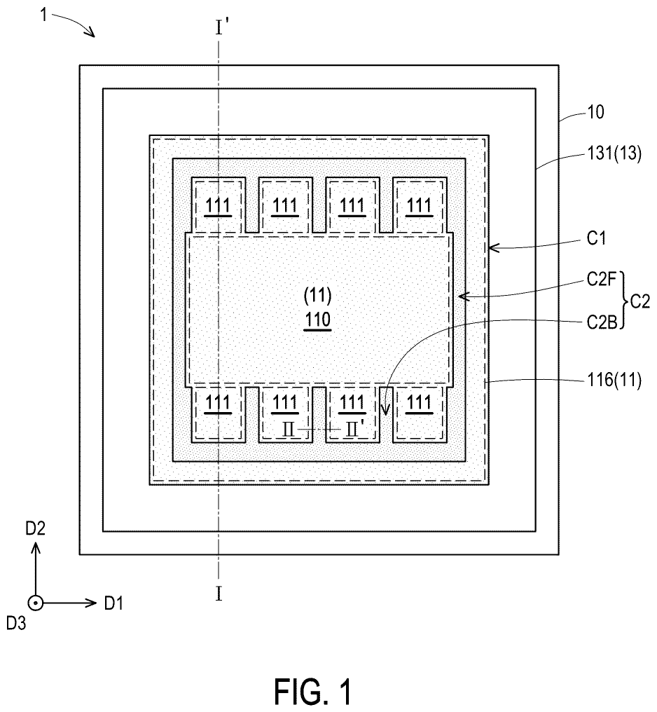

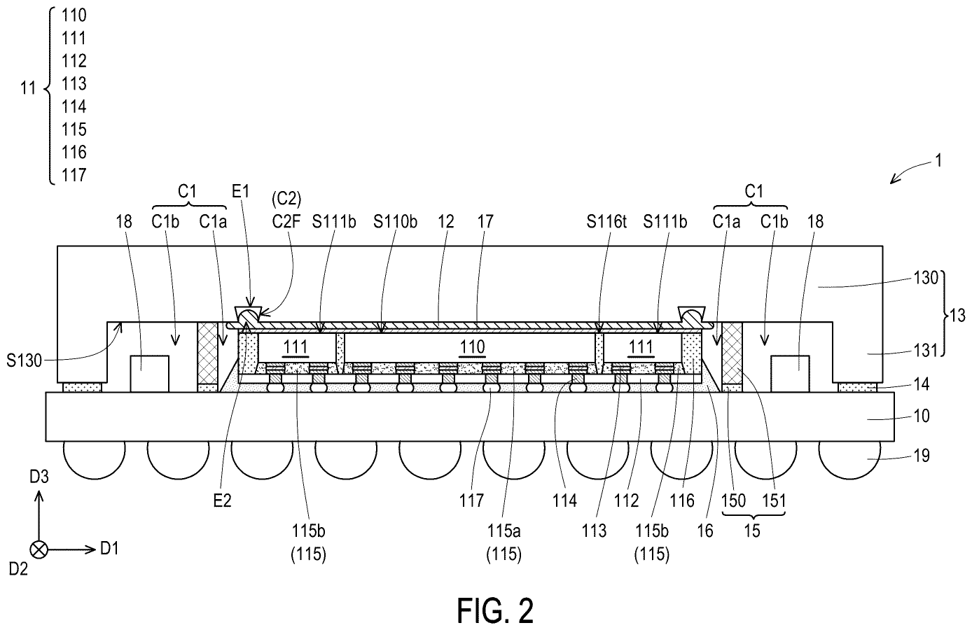

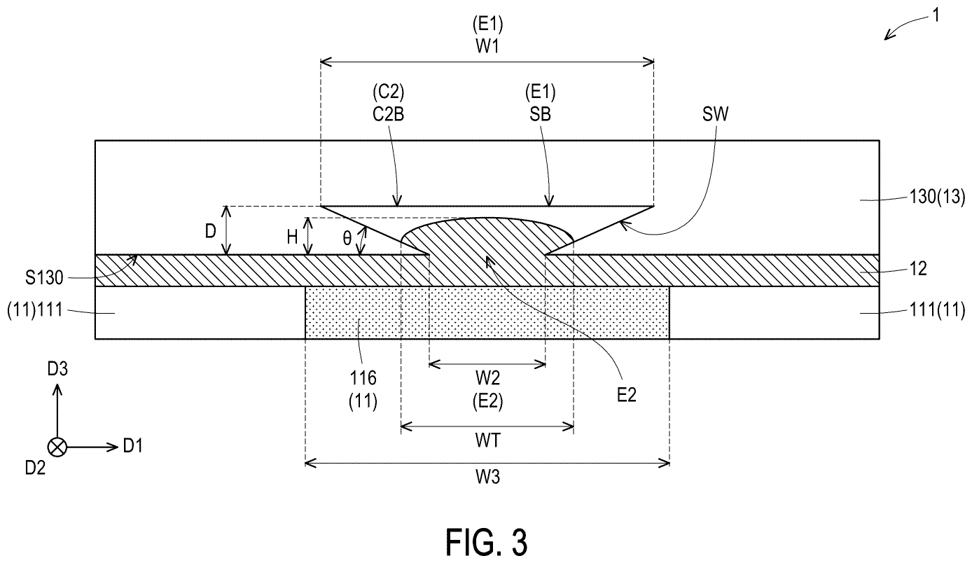

FIG. 1 illustrates a top view of a semiconductor device in accordance with some embodiments of the present disclosure. FIG. 2 illustrates a cross-sectional view of a semiconductor device in accordance with some embodiments of the present disclosure. FIG. 3 illustrates an enlarged partial cross-sectional view of a semiconductor device in accordance with some embodiments of the present disclosure. For example, FIG. 2 is a schematic cross-sectional view corresponding to the section line I-I′ in FIG. 1, and FIG. 3 is a schematic partial cross-sectional view corresponding to the section line II-II′ in FIG. 1. In FIG. 3, the lower half of the semiconductor device 1 is omitted to clearly show a second cavity C2, a thermal conductive bonding layer 12 and a semiconductor package 11 of the semiconductor device 1 in accordance with some embodiments of the present disclosure.

Referring to FIG. 1 to FIG. 3, a semiconductor device 1 includes, for example, a substrate 10, a semiconductor package 11, a thermal conductive bonding layer 12 and a lid 13, but not limited thereto. The semiconductor device 1 may further include one or more elements and/or layers according to needs.

The substrate 10 may include elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the substrate 10 includes silicon on insulator (SOI) or silicon-germanium on insulator (SGOI). In some embodiments, the substrate 10 includes active components (e.g., transistors or the like) formed therein. In some embodiments, the substrate 10 includes passive components (e.g., resistors, capacitors, inductors, or the like) formed therein. In some embodiments, the substrate 10 includes a silicon wafer. In some embodiments, the substrate 10 is a package substrate or ball grid array (BGA) substrate including one or more active components, passive components, or a combination thereof. In some embodiments, the substrate 10 further includes interconnection structures and/or redistribution layers (not shown) to connect various components therein to form functional circuitry. In some embodiments, the substrate 10 may be provided for dual-side electrical connection.

The semiconductor package 11 is disposed on the substrate 10. The semiconductor package 11 may include at least one semiconductor die. In some embodiments, the semiconductor package 11 includes a plurality of semiconductor dies, such as a first semiconductor die 110 and a plurality of second semiconductor dies 111, but not limited thereto. In some embodiments, as shown in FIG. 1, the plurality of second semiconductor dies 111 is arranged along a first direction D1, and the plurality of second semiconductor dies 111 is arranged on two opposite sides of the first semiconductor die 110 along a second direction D2. The first direction D1 and the second direction D2 are both perpendicular to a thickness direction (e.g., a third direction D3) of the substrate 10. The second direction D2 intersects the first direction D1 and is, for example, perpendicular to each other.

The plurality of semiconductor dies may include one or more logic dies (e.g., a central processing unit (CPU) die, a graphic processing unit (GPU) die, a micro control unit (MCU) die, an input-output (I/O) die, a baseband (BB) die, an application processor (AP) die, a field-programmable gate array (FPGA) die, an application specific integrated circuit (ASIC) die, a system-on-chip (SoC) die, a system-on-integrated-chip (SoIC) die, a microcontroller die, or the like), one or more memory dies (e.g., a dynamic random access memory (DRAM) die, a static random access memory (SRAM) die, a high bandwidth memory (HBM) die, or the like), one or more power management dies (e.g., a power management integrated circuit (PMIC) die), one or more radio frequency (RF) dies, one or more sensor dies, one or more micro-electro-mechanical-system (MEMS) dies, one or more signal processing dies (e.g., a digital signal processing (DSP) die), one or more front-end dies (e.g., an analog front-end (AFE) die), the like, or a combination thereof.

In some embodiments, the plurality of semiconductor dies may be the same type of dies or perform the same functions. In some other embodiments, the plurality of semiconductor dies may be different types of dies or perform different functions. In some embodiments, the first semiconductor die 110 includes a logic die, and the plurality of second semiconductor dies 111 includes memory dies.

In some embodiments, as shown in FIG. 2, the semiconductor package 11 further includes an interposer 112, connectors 113, through vias 114, an underfill 115, an encapsulant 116 and connectors 117 in addition to the plurality of semiconductor dies.

The plurality of semiconductor dies is bonded via the connectors 113 to through vias 114 formed within the interposer 112. A material of the connectors 113 may include copper, copper alloys, or other conductive materials, and the connectors 113 may be formed by deposition, plating, or other suitable techniques. In some embodiments, the connectors 113 are prefabricated structures attached to contact pads (not marked) of the plurality of semiconductor dies. In some embodiments, the connectors 113 are solder balls, metal pillars, controlled collapse chip connection bumps, micro bumps, bumps formed via electroless nickel-electroless palladium immersion gold technique (ENEPIG), combinations thereof (e. g, a metal pillar with a solder ball attached), or the like. The interposer 112 may be made of a semiconductor material similar to those previously discussed with reference to the substrate 10, and will not be repeated here. A material of the through vias 114 may include one or more metals such as copper, titanium, tungsten, aluminum, the alloys, the combinations or the like.

Referring to FIG. 2, the underfill 115 may be disposed between the plurality of semiconductor dies and the interposer 112 to protect the connectors 113 against thermal or physical stresses and secure the electrical connection of the plurality of semiconductor dies with the through vias 114. In some embodiments, the underfill 115 is formed by capillary underfill filling (CUF). A dispenser (not shown) may apply a filling material (not shown) along the perimeter of the semiconductor dies. In some embodiments, a heating process is performed to let the filling material penetrate in the interstices defined by the connectors 113 between the plurality of semiconductor dies and the interposer 112 by capillarity. In some embodiments, a curing process is performed to consolidate the underfill 115. In some embodiments, a material of the underfill 115 includes a molding compound, a moldable polymer, a combination thereof, or the like. The molding compound includes, for example, an epoxy, a resin, an UV or thermally cured polymer. In some embodiments, the underfill 115 includes underfill portions 115a and 115b spaced apart from each other, wherein the underfill portion 115a is formed between the first semiconductor die 110 and the interposer 112, and the underfill portions 115b are formed between the plurality of second semiconductor dies 111 and the interposer 112. In some alternative embodiments, a single underfill (not shown) may extend below the plurality of semiconductor dies depending on the spacing and relative positions of the plurality of semiconductor dies.

The encapsulant 116 may be formed on the interposer 112. The encapsulant 116 may cover the underfill 115 and laterally wrap the plurality of semiconductor dies. In some embodiments, the encapsulant 116 is formed by completely covering the plurality of semiconductor dies with an encapsulation material (not shown), and then performing a planarization process (e.g., a mechanical grinding process and/or a chemical mechanical polishing step) until backside surfaces S110b and S111b of the plurality of semiconductor dies are exposed. In some embodiments, the top surface S116t of the encapsulant 116 and the backside surfaces S110b and S111b of the plurality of semiconductor dies are flush or coplanar. In some embodiments, the encapsulation material may be a molding compound, a molding underfill, a resin (such as an epoxy resin), glue, or the like. In some embodiments, the encapsulation material is formed by an over-molding process. In some embodiments, the encapsulation material is formed by at least one of a compression molding process, an immersion molding process and a transfer molding process. In some embodiments, the encapsulation material may require a curing process.

The through vias 114 may be bonded to the substrate 10 via the connectors 117. A method of forming the connectors 117 and a material of the connectors 117 may be similar to those previously discussed with reference to the connectors 113, and will not be repeated here.

Referring to FIG. 2 and FIG. 3, the thermal conductive bonding layer 12 is disposed on the backside of the semiconductor package 11. In some embodiments, the semiconductor package 11 is completely covered by the thermal conductive bonding layer 12. In some embodiments, edges of the thermal conductive bonding layer 12 extend beyond edges of the semiconductor package 11 so that an orthographic projection of the semiconductor package 11 on the substrate 10 falls within an orthographic projection of the thermal conductive bonding layer 12 on the substrate 10.

The thermal conductive bonding layer 12 is configured to reduce contact thermal resistance and improve heat dissipation performance. The thermal conductive bonding layer 12 may include a thermal interface material (TIM), graphite, solder paste, nano silver paste, or other bonding material with high thermal conductivity. The thermal interface material may include a thermal grease (or thermal paste), a thermal gel, a thermal pad, a phase-change material (PCM), a phase change metal alloy, or a thermal conductive adhesive. Composition of the thermal grease may include silicon oil base, zinc oxide (ZnO), or silver (Ag), but not limited thereto. Composition of the thermal gel may include aluminum (Al), silver (Ag), silicon oil, olefin, or paraffin wax, but not limited thereto. Composition of the thermal pad may include silicone rubber, glass fiber, polyester based material, or silicone oil filled material, but not limited thereto. Composition of the phase-change material may include polyolefin resin, acrylic, aluminum (Al), aluminum oxide, or carbon nanofiber tube, but not limited thereto. Composition of the phase change metal alloy may include indium (In), alloy of indium (In) and silver (Ag), alloy of tin (Sn), silver (Ag) and copper (Cu), alloy of indium (In), tin (Sn) and bismuth (Bi), but not limited thereto. Composition of the thermal conductive adhesive may include epoxy, iron (Fe), silver (Ag), or nickel (Ni), but not limited thereto. In some embodiments, the thermal conductive bonding layer 12 is disposed on the semiconductor package 11 through coating, printing, placing, etc. In some embodiments, the thermal conductive bonding layer 12 may require curing. In some alternative embodiments, the thermal conductive bonding layer 12 may not require curing.

Referring to FIG. 2 and FIG. 3, a lid 13 is provided and attached to the substrate 10 via a bonding layer 14, and the lid 13 is attached to the semiconductor package 11 via the thermal conductive bonding layer 12. At least one thermal process may be performed to attach the lid 13 to the semiconductor package 11 and the substrate 10. The lid 13 is configured to prevent coolant (not shown) from contacting the elements thereunder. In some embodiments, a material of the lid 13 includes a thermally conductive material. In some embodiments, the material of the lid 13 includes metals or metal alloys, such as copper, aluminum, their alloys, the combinations thereof or the like. In some embodiments, the material of the lid 13 includes a semiconductor material such as silicon. In some embodiments, the material of the lid 13 includes polyimide, epoxy resin, acrylic resin (e.g., polymethylmethacrylate, PMMA), phenol resin, benzocyclobutene (BCB), polybenzooxazole (PBO), or any other suitable polymer-based material. In some embodiments, the material of the lid 13 includes metal diamond composites, such as Cu diamond, silver diamond, Al diamond, or the like. In some embodiments, the lid 13 is molded, forged, 3D-printed, grown, or fabricated according to any other suitable technique. In some embodiments, multiple portions (e.g., a plate portion 130 and a frame portion 131) of the lid 13 are fabricated separately and then assembled through additional elements (e.g., screws, adhesives, or combination thereof). In some alternative embodiments, multiple portions of the lid 13 are fabricated separately and then assembled (e.g., welded) without additional elements. In other alternative embodiments, multiple portions of the lid 13 are integrally formed.

The lid 13 has, for example, a first cavity C1 and a second cavity C2 open to and connected to the first cavity C1. When the lid 13 is attached to the substrate 10, the semiconductor package 11 is located in the first cavity C1, and the thermal conductive bonding layer 12 is partially filled into the second cavity C2. For example, the second cavity C2 is concave from the first cavity C1 into the lid 13. From FIG. 2 to FIG. 3, the thermal conductive bonding layer 12 is mainly disposed on the semiconductor package 11 in the first cavity C1 and partially fills or extends into the second cavity C2. In some embodiments, the lid 13 includes a plate portion 130 and a frame portion 131 located at edges of the plate portion 130 and protruding from the plate portion 130 towards the substrate 10, the plate portion 130 and the frame portion 131 form the first cavity C1 facing the substrate 10, and the second cavity C2 extends from the inner surface S130 of the plate portion 130 facing the semiconductor package 11 into the plate portion 130 of the lid 13 with a depth along the thickness direction without penetrating through the plate portion 130. In some embodiments, the surface S130 of the plate portion 130 facing the semiconductor package 11 is level with a boundary between the first cavity C1 and the second cavity C2. In some embodiments, the plate portion 130 extends substantially parallel to the substrate 10, and the frame portion 131 extends substantially perpendicular to the substrate 10.

In some embodiments, the arrangement of one or more second cavities C2 can assist accommodating the extra thermal conductive bonding layer 12, when the volume of the thermal conductive bonding layer 12 is in excess or when the volume of the thermal conductive bonding layer 12 expands due to temperature rise in subsequent processes. That is, the second cavity C2 can accommodate the outwardly expanding thermal conductive bonding layer 12. In addition, the second cavity C2 can be used for outgassing during the subsequent processes. Specifically, the second cavity C2 is open to and in fluid or gas communication with the first cavity C1, and the thermal conductive bonding layer 12 arranged on the semiconductor package 11 inside the first cavity C1 faces the second cavity C2. Gas residues at the interface between the thermally conductive adhesive layer 12 and the adjacent layer(s) can be expelled through the second cavity C2, thereby reducing the voids generated inside the thermally conductive adhesive layer 12.

In some embodiments, the second cavity C2 is disposed outside the heat-producing regions (e.g., regions where the plurality of semiconductor dies is located) of the semiconductor package 11, i.e., locations of the second cavity C2 and the plurality of semiconductor dies are not overlapped in the third direction D3, so as to maintain the thermal dissipation performance (such as thermal conduction efficiency) of the heat-producing regions. For example, an orthogonal projection of the second cavity C2 on the semiconductor package 11 is overlapped with the encapsulant 116 beside the at least one semiconductor die. Specifically, the orthogonal projection of the second cavity C2 on the semiconductor package 11 is located outside spans of the plurality of semiconductor dies and located in the span of the encapsulant 116 (e.g., the span of the second cavity C2 is overlapped with the encapsulant 116). As shown in FIG. 1, the plurality of semiconductor dies (e.g., the first semiconductor die 110 and the plurality of second semiconductor dies 111) is surrounded by the ring-shaped second cavity C2 in a top view of the semiconductor device 1. In some embodiments, the second cavity C2 includes a frame portion (frame trench portion) C2F and a branch portion (branch trench portion) C2B located within and connected to the frame portion C2F. In some embodiments, the semiconductor dies (including the first semiconductor die 110 and the plurality of second semiconductor dies 111) are surrounded by the frame portion C2F, and two adjacent dies (e.g., two adjacent second semiconductor dies 111) among the plurality of semiconductor dies are separated by the branch portion C2B in the top view of the semiconductor device 1. In some embodiments, the second cavity C2 includes a plurality of branch portions C2B, and each of the plurality of branch portions C2B is disposed between two corresponding dies (e.g., along the facing sides of the two adjacent second semiconductor dies 111) among the plurality of semiconductor dies. In some embodiments, an extension direction of the branch portion C2B is perpendicular to an arrangement direction of the plurality of semiconductor dies. For example, an arrangement direction of the plurality of second semiconductor dies 111 is the second direction D2, and an extension direction of the branch portion C2B is the first direction D1. In some embodiments, as shown in FIG. 2, the second cavity C2 (e.g., the frame portion C2F of the second cavity C2) is located over the encapsulant 116 along the periphery of the semiconductor package 11, namely, the second cavity C2 is overlapped with the encapsulant 116 at the border of the semiconductor package 11. In some embodiments, as shown in FIG. 3, the orthogonal projection of the second cavity C2 on the semiconductor package 11 is located within the area of the encapsulant 116 and between two adjacent semiconductor dies (e.g., not falling within the areas of the two adjacent second semiconductor dies 111) among the plurality of semiconductor dies. Namely, the span of the second cavity C2 is overlapped with the span of the encapsulant 116 between two adjacent semiconductor dies (e.g., not overlapping with the spans of the two adjacent second semiconductor dies 111) among the plurality of semiconductor dies.

In some embodiments, in a cross-sectional view of the semiconductor device 1, as shown in FIG. 2 or FIG. 3, the second cavity C2 has slant sidewalls SW, and the slant sidewall SW is inclined from the inner surface S130 toward a bottom surface SB of the second cavity C2 so as to define a neck portion E2 (neck opening; also referred to as “second portion”) and a hollow recess portion E1 (also referred to as “first portion”) wider than the neck portion E2. As seen in FIG. 2, the neck portion E2 is located between the recess portion E1 and the first cavity C1 (i.e., the neck portion E2 is joined with the first cavity C1). For example, a width (e.g., a maximum width) of the recess portion E1 is W1, a width (e.g., a maximum width) of the neck portion E2 is W2, and W2<W1. During the temperature variation processes (e.g., a thermal cycle testing process), the substrate 10, the semiconductor package 11 and the thermally conductive adhesive layer 12 is pulled downwardly by gravity. However, the narrower neck portion E2 can promote the flow or move of the thermal conductive bonding layer 12 into the second cavity C2, which further provides a pull force for securing the attachment of the lid 13 to the thermal conductive bonding layer 12. Through the arrangement of the second cavity C2, the stress at the bonding interface between the lid 13 and the thermal conductive bonding layer 12 is decreased, the connection/bonding between the thermal conductive bonding layer and the lid is improved with less cracks generated at the interface between the lid and the thermal conductive bonding layer.

In some embodiments, as shown in FIG. 2 or FIG. 3, the second cavity C2 has slant sidewalls SW inwardly inclined or curved, and the angle θ of the sidewall SW to the inner surface S130 is a sharp angle. For example, in FIG. 3, the sidewall SW of the second cavity C2 includes an inclined planar surface, and the bottom surface SB includes a flat planar surface, but not limited thereto. In some embodiments, the second cavity C2 may be made by a milling tool, e.g., a milling tool having a chamfer end with a shape corresponding to the shape of the second cavity C2.

In some embodiments, as shown in FIG. 3, as the lid 13 is attached to the semiconductor package 11, a portion of the thermal conductive bonding layer 12 is filled into the second cavity C2. As seen in FIG. 3, the second cavity C2 is partially filled with the thermal conductive bonding layer 12 (at least the neck portion E2 is filled with the thermal conductive bonding layer 12), and a width (e.g., a maximum width) of the thermal conductive bonding layer 12 in the second cavity C2 is WT, and W2<W1≤WT. In some embodiments, as shown in FIG. 3, a depth of the second cavity C2 is D, a height of the thermal conductive bonding layer 12 filled in the second cavity C2 is H, and 0<H≤D. In some embodiments, as shown in FIG. 3, a width (shortest distance) of the encapsulant sandwiched between the two adjacent semiconductor dies (e.g., the two most adjacent second semiconductor dies 111) is W3, and W2<W1≤W3. In FIG. 3, the thermal conductive bonding layer 12 located in the second cavity C2 that is constrained and tied by the narrower neck portion E2 provides a pulling force (like a bolt or nail) to secure the attachment of the lid 13 and the thermal conductive bonding layer 12. Note that the design parameters (e.g., shapes, widths, lengths, depths or the like) of the frame portion C2F and the branch portion C2B of the second cavity C2 in the top view or the cross-sectional view are not limited to those shown in the figures and may be changed according to needs.

In some embodiments, as shown in FIG. 2, the semiconductor device 1 further includes a bonding layer 14 that bonds the frame portion 131 to the substrate 10. In some embodiments, the bonding layer 14 is formed on a bottom surface of the frame portion 131, and then the lid 13 on which the bonding layer 14 is formed is attached to the substrate 10. In some alternative embodiments, the bonding layer 14 is formed on the substrate 10, and then the lid 13 is attached to the bonding layer 14 on the substrate 10. The bonding layer 14 may be made of a heat resistant and waterproof material, and the bonding layer 14 may provide buffer or compensation for assembly of the lid 13. In some embodiments, a material of the bonding layer 14 includes thermo curable adhesives, photocurable adhesives, thermally conductive adhesive, thermosetting resin, waterproof adhesive, lamination adhesive or a combination thereof. In some embodiments, the material of the bonding layer 14 includes a thermally conductive adhesive. In some embodiments, the bonding layer 14 includes a metallic layer (not shown) with solder paste (not shown) deposited thereon. In some embodiments, the bonding layer 14 is epoxy, glue, or the like. In some alternative embodiments, the lid 13 is fixed on the substrate 10 through a fixing mechanism (e.g., screws), and the bonding layer 14 may be omitted. In some embodiments, the semiconductor device 1 further includes a bonding layer 15 that bonds the plate portion 130 to the substrate 10. A material and forming method of the bonding layer 15 may be similar to those previously discussed with reference to the bonding layer 14, and will not be repeated here.

In some embodiments, as shown in FIG. 2, the semiconductor package 11 and the thermal conductive bonding layer 12 are laterally surrounded by the bonding layer 15. In some embodiments, after attachment, the first cavity C1 is divided by the bonding layer 15 into a first sub cavity C1a in which the semiconductor package 11 is disposed and a second sub cavity C1b located between the first sub cavity C1a and the frame portion 131. In some embodiments, the bonding layer 15 helps to constrain the thermal conductive bonding layer 12 and/or an underfill 16 inside the first sub cavity C1a.

In some embodiments, although not shown, the second sub cavity C1b and external of the semiconductor device 1 are in fluid/gas communication via a first gas discharge hole of the bonding layer 14, and the first sub cavity C1a and the second sub cavity C1b are in gas communication via a second gas discharge hole of the bonding layer 15. In some embodiments, as shown in FIG. 2, the bonding layer 15 includes a first layer 150 and a second layer 151 sequentially stacked on the substrate 10. The first layer 150 may be formed together with the bonding layer 14, but not limited thereto. In some embodiments, the second gas discharge hole is in the second layer 151 (e.g., a portion of the second layer 151 is removed to form the second gas discharge hole), and thereby the second gas discharge hole is higher than the first gas discharge hole. The first gas discharge hole and the second gas discharge hole help balance the air pressure, and thereby maintaining the integrity of the bonding layer 15 or reducing the chance of the bonding layer 15 being broke by the thermal conductive bonding layer 12 due to air pressure.

In some embodiments, the semiconductor device 1 further includes an underfill 16 disposed between the semiconductor package 11 and the substrate 10 and laterally surrounded by the bonding layer 15. The underfill 16 helps to protect the connectors 117 against thermal or physical stresses and secure the electrical connection of the semiconductor dies with the substrate 10. A material and forming method of the underfill 16 may be similar to those previously discussed with reference to the underfill 115, and will not be repeated here.

In some embodiments, the semiconductor device 1 further includes a backside metal layer 17 disposed between the thermal conductive bonding layer 12 and the semiconductor package 11 to improve heat dissipation or conductivity. The backside metal layer 17 may be formed at least on the backside surface (including the backside surfaces S110b and S111b of the semiconductor dies) of the semiconductor package 11. In some embodiments, although not shown, the backside metal layer 17 is further formed on side surfaces of the semiconductor package 11 and on the underfill 16. In some embodiments, after the semiconductor package 11 and the underfill 16 are formed on the substrate 10, a shielding element (not shown; e.g., a jig or a protection tape) is disposed on the substrate 10. The shielding element has an opening that exposes the region (e.g., a region in which the semiconductor package 11 and the underfill 16 are located) where the backside metal layer 17 is to be formed. The material of the backside metal layer 17 is then formed on the shielding element and the elements (e.g., the semiconductor package 11 and the underfill 16) exposed by the opening of the shielding element through a sputtering process, a physical vapor deposition (PVD) process, a plating process, an electron beam evaporation process, or the like. In some embodiments, the backside metal layer 17 may include a stacked layer of titanium (Ti) and copper (Cu), a stacked layer of diamond-like carbon (DLC), titanium (Ti) and copper (Cu), a stacked layer of titanium (Ti), copper (Cu) and nickel (Ni), or a stacked layer of titanium (Ti), copper (Cu) and vanadium (V), but not limited thereto. In some embodiments, the backside metal layer 17 is formed from a conductive material or metal, such as Ag, Au, Ti, NiV, Al, TiN, Cu, Sn, the like, or a combination thereof. In some embodiments, the backside metal layer 17 may be formed by depositing a seed layer over the semiconductor package 11, and then electroplating the conductive material onto the seed layer. In some embodiments, a width of the backside metal layer 17 is smaller than a width of the thermal conductive bonding layer 12. For example, edges of the backside metal layer 17 may be aligned with edges of the semiconductor package 11, and edges of the thermal conductive bonding layer 12 may extend outward from edges of the backside metal layer 17, but not limited thereto.

In some embodiments, the semiconductor device 1 further includes a passive component 18 disposed between the frame portion 131 and the semiconductor package 11. For example, the passive component 18 is disposed on and electrically connected to the substrate 10. In the embodiments in which the bonding layer 15 is included in the semiconductor device 1, the passive component 18 can be disposed in the second sub cavity C1b and can be separated from the thermal conductive bonding layer 12 via the bonding layer 15. In some embodiments, the passive component 18 is a surface mount device (SMD) electrically connected to the substrate 10. In some embodiments, the semiconductor device 1 includes a plurality of passive components 18.

In some embodiments, the semiconductor device 1 further includes a plurality of connectors 19. The plurality of connectors 19 is disposed on a surface of the substrate 10 opposite to the plurality of passive components 18. A method of forming the connectors 19 and a material of the connectors 19 may be similar to those previously discussed with reference to the connectors 117, and will not be repeated here. In some embodiments, although not shown, the substrate 10 may be bonded to a printed circuit board via the connectors 19.

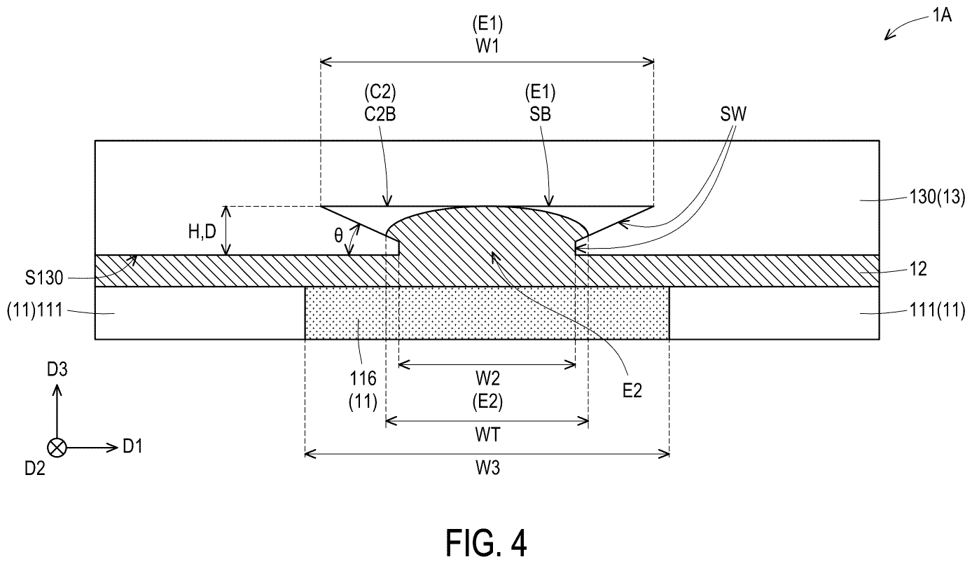

FIG. 4 illustrates an enlarged partial cross-sectional view of a semiconductor device in accordance with some embodiments of the present disclosure. In FIG. 4, the lower half of the semiconductor device 1A is omitted to clearly show the second cavity C2, the thermal conductive bonding layer 12 and the semiconductor package 11 of the semiconductor device 1A in accordance with some embodiments of the present disclosure.

In some embodiments, as shown in FIG. 4, the sidewall surface SW of the second cavity C2 includes an inclined surface as well as a vertical surface connected between the inclined surface and the surface S130 of the plate portion 130 facing the semiconductor package 11, but not limited thereto. For example, the inclined surface may be connected between the vertical surface and the surface S130 of the plate portion 130 facing the semiconductor package 11. In some embodiments, as shown in FIG. 4, the height H of the thermal conductive bonding layer 12 in the second cavity C2 is equal to the depth D of the second cavity C2, but not limited thereto. For example, the height H of the thermal conductive bonding layer 12 in the second cavity C2 may be smaller than the depth D of the second cavity C2.

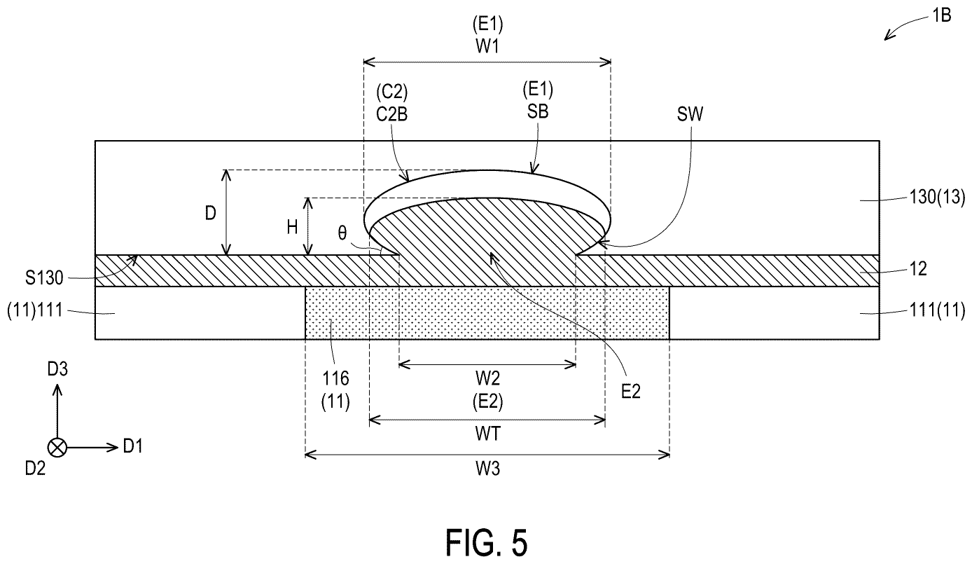

FIG. 5 illustrates an enlarged partial cross-sectional view of a semiconductor device in accordance with some embodiments of the present disclosure. In FIG. 5, the lower half of the semiconductor device 1B is omitted to clearly show the second cavity C2, the thermal conductive bonding layer 12 and the semiconductor package 11 of the semiconductor device 1B in accordance with some embodiments of the present disclosure.

In some embodiments, as shown in FIG. 5, the sidewall surface SW of the second cavity C2 includes a curved surface, but not limited thereto. For example, the sidewall surface SW of the second cavity C2 may include at least one curved surface, at least one inclined surface, at least one vertical surface, at least one horizontal surface or a combination of at least two of the above. In some embodiments, as shown in FIG. 5, the height H of the thermal conductive bonding layer 12 in the second cavity C2 is smaller than the depth D of the second cavity C2, but not limited thereto. For example, the height H of the thermal conductive bonding layer 12 in the second cavity C2 may be equal to the depth D of the second cavity C2.

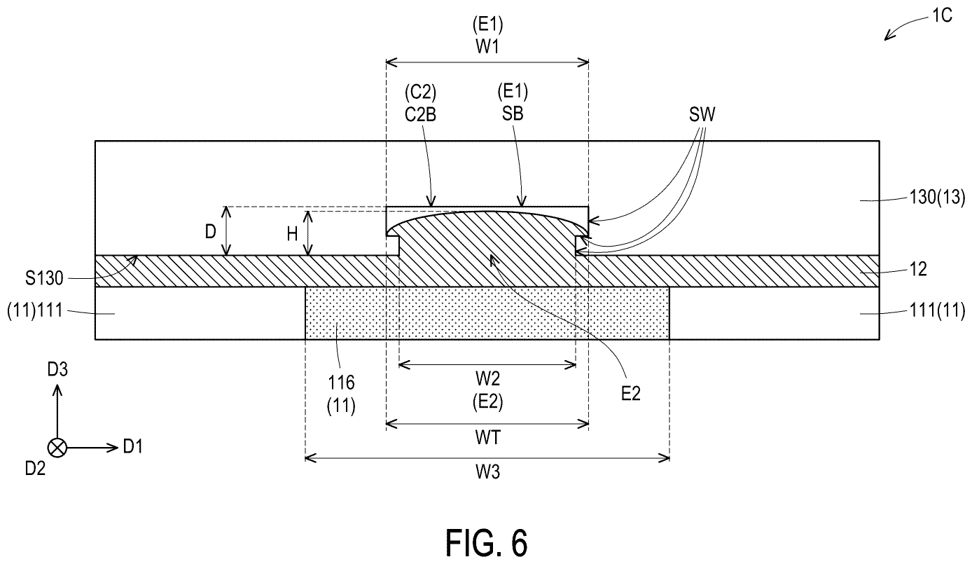

FIG. 6 illustrates an enlarged partial cross-sectional view of a semiconductor device in accordance with some embodiments of the present disclosure. In FIG. 6, the lower half of the semiconductor device 1C is omitted to clearly show the second cavity C2, the thermal conductive bonding layer 12 and the semiconductor package 11 of the semiconductor device 1C in accordance with some embodiments of the present disclosure.

In some embodiments, as shown in FIG. 6, the sidewall surface SW of the second cavity C2 includes two vertical surfaces and a horizontal surface connected between the two vertical surfaces, but not limited thereto. For example, the sidewall surface SW of the second cavity C2 may include at least one curved surface, at least one inclined surface, at least one vertical surface, at least one horizontal surface or a combination of at least two of the above. In some embodiments, as shown in FIG. 6, the height H of the thermal conductive bonding layer 12 in the second cavity C2 is smaller than the depth D of the second cavity C2, but not limited thereto. For example, the height H of the thermal conductive bonding layer 12 in the second cavity C2 may be equal to the depth D of the second cavity C2.

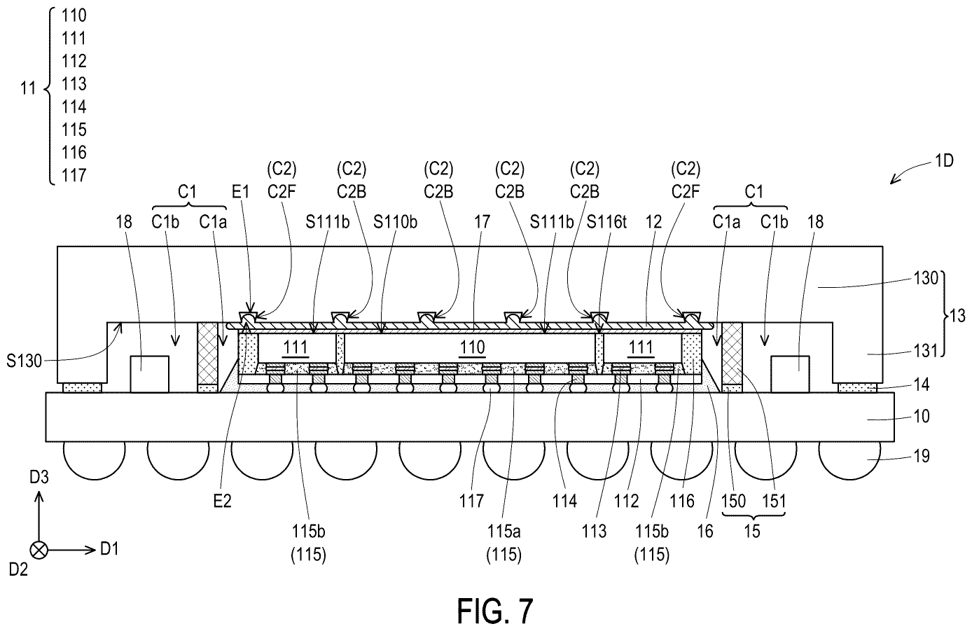

FIG. 7 illustrates a cross-sectional view of a semiconductor device in accordance with some embodiments of the present disclosure. In some embodiments, as shown in FIG. 7, the second cavity C2 (e.g., the branch portions C2B of the second cavity C2) is overlapped with at least one of the plurality of semiconductor dies. For example, the branch portions C2B of the second cavity C2 is overlapped with the first semiconductor die 110 to further improve the connection/bonding between the thermal conductive bonding layer 12 and the lid 13 or to further reduce cracks generated at the interface between the lid 13 and the thermal conductive bonding layer 12.

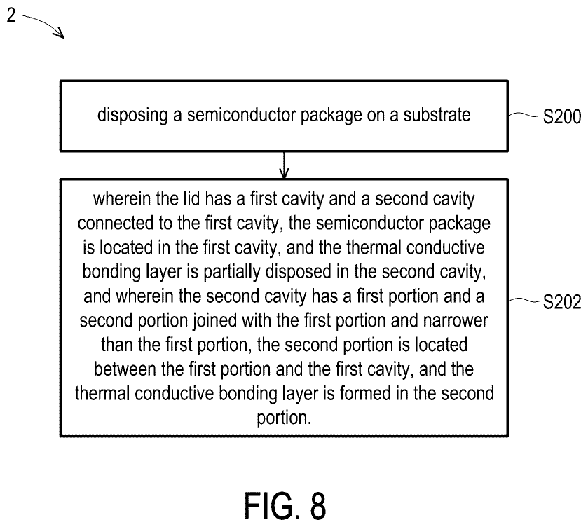

FIG. 8 illustrates a flow chart of a method for manufacturing a semiconductor device in accordance with some embodiments of the present disclosure. Referring to FIG. 8, the method 2 for manufacturing a semiconductor device in accordance with some embodiments of the present disclosure includes disposing a semiconductor package 11 on a substrate 10 (step S200; see FIG. 2 or FIG. 7) and attaching a lid 13 to the semiconductor package 11 via a thermal conductive bonding layer 12, wherein the lid 13 has a first cavity C1 and a second cavity C2 connected to the first cavity C1, the semiconductor package 11 is located in the first cavity C1, and the thermal conductive bonding layer 12 is partially disposed in the second cavity C2, and wherein the second cavity C2 has a first portion (recess portion E1) and a second portion (neck portion E2) joined with the first portion and narrower than the first portion, the second portion is located between the first portion and the first cavity C1, and the thermal conductive bonding layer 12 is formed in the second portion (step S202; see FIG. 2 or FIG. 7).

In some embodiments, as shown in FIG. 2 or FIG. 7, the method for manufacturing the semiconductor device further includes attaching the lid 13 to the substrate 10 through a bonding layer such as the bonding layer 14 or the bonding layer 15. In some embodiments, as shown in FIG. 2 or FIG. 7, the lid 13 includes a plate portion 130 and a frame portion 131 located at edges of the plate portion 130 and protrudes towards the substrate 10, wherein the plate portion 130 is attached to the substrate 10 through the bonding layer 15. In some embodiments, as shown in FIG. 2 or FIG. 7, the method for manufacturing the semiconductor device further includes disposing a passive component 18 between the frame portion 131 and the bonding layer 15.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor device includes a substrate, a semiconductor package, a thermal conductive bonding layer and a lid. The semiconductor package is disposed on the substrate. The thermal conductive bonding layer is disposed on the semiconductor package. The lid is attached to the semiconductor package via the thermal conductive bonding layer. The lid has a first cavity and a second cavity connected to the first cavity. The semiconductor package is located in the first cavity, and the thermal conductive bonding layer is partially disposed in the second cavity. The second cavity has a first portion and a second portion joined with the first portion and narrower than the first portion, the second portion is located between the first portion and the first cavity, and the thermal conductive bonding layer is formed in the second portion. In some embodiments, the lid includes a plate portion and a frame portion located at edges of the plate portion and protrudes towards the substrate, wherein a surface of the plate portion facing the semiconductor package is higher than the first cavity and lower than the second cavity. In some embodiments, the second cavity has a curved surface or an inclined surface. In some embodiments, a maximum width of the first portion is W1, a width of the second portion is W2, a maximum width of the thermal conductive bonding layer in the second cavity is WT, and W2<W1≤WT. In some embodiments, a depth of the second cavity is D, a height of the thermal conductive bonding layer in the second cavity is H, and 0<H≤D. In some embodiments, the semiconductor package includes an encapsulant, and the second cavity is overlapped with the encapsulant. In some embodiments, the semiconductor package further includes a plurality of semiconductor dies laterally wrapped by the encapsulant, and the second cavity is overlapped with the encapsulant between two adjacent semiconductor dies among the plurality of semiconductor dies. In some embodiments, a width of the first portion is W1, a width of the second portion is W2, a width of the encapsulant between the two adjacent semiconductor dies is W3, and W2<W1≤W3.

According to some embodiments, a semiconductor device includes a substrate, a semiconductor package, a thermal conductive bonding layer and a lid. The semiconductor package is disposed on the substrate. The semiconductor package includes at least one semiconductor die and an encapsulant laterally wraps the at least one semiconductor die. The thermal conductive bonding layer is disposed on the semiconductor package. The lid is attached to the semiconductor package via the thermal conductive bonding layer. The lid has a first cavity and a second cavity connected to the first cavity. The semiconductor package is in the first cavity, and the thermal conductive bonding layer is partially in the second cavity. An orthogonal projection of the second cavity on the semiconductor package is overlapped with the encapsulant beside the at least one semiconductor die. In some embodiments, the second cavity is located over the encapsulant along a periphery of the semiconductor package. In some embodiments, the at least one semiconductor die includes a first die and a second die, and the orthogonal projection of the second cavity on the semiconductor package is located on the encapsulant between the first die and the second die. In some embodiments, the semiconductor device further includes a backside metal layer disposed between the thermal conductive bonding layer and the semiconductor package. In some embodiments, a width of the backside metal layer is smaller than a width of the thermal conductive bonding layer. In some embodiments, the lid includes a plate portion and a frame portion located at edges of the plate portion and protrudes towards the substrate, wherein a surface of the plate portion facing the semiconductor package is higher than the first cavity and lower than the second cavity. In some embodiments, the semiconductor device further includes a bonding layer disposed between the substrate and the frame portion or between the substrate and the plate portion. In some embodiments, the semiconductor device further includes a passive component disposed between the frame portion and the semiconductor package.

According to some embodiments, a method for manufacturing a semiconductor device includes: disposing a semiconductor package on a substrate; and attaching a lid to the semiconductor package via a thermal conductive bonding layer, wherein the lid has a first cavity and a second cavity connected to the first cavity, the semiconductor package is located in the first cavity, and the thermal conductive bonding layer is partially disposed in the second cavity, and wherein the second cavity has a first portion and a second portion joined with the first portion and narrower than the first portion, the second portion is located between the first portion and the first cavity, and the thermal conductive bonding layer is formed in the second portion. In some embodiments, the method for manufacturing the semiconductor device further includes attaching the lid to the substrate through a bonding layer. In some embodiments, the lid includes a plate portion and a frame portion located at edges of the plate portion and protrudes towards the substrate, wherein the plate portion is attached to the substrate through the bonding layer. In some embodiments, the method for manufacturing the semiconductor device further includes disposing a passive component between the frame portion and the bonding layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a semiconductor package disposed on the substrate;
a thermal conductive bonding layer disposed on the semiconductor package; and
a lid attached to the semiconductor package via the thermal conductive bonding layer,
wherein the lid has a first cavity and a second cavity connected to the first cavity, the semiconductor package is located in the first cavity, and the thermal conductive bonding layer is partially disposed in the second cavity, and
wherein the second cavity has a first portion and a second portion joined with the first portion and narrower than the first portion, the second portion is located between the first portion and the first cavity, and the thermal conductive bonding layer is formed in the second portion.

2. The semiconductor device of claim 1, wherein the lid comprises:
a plate portion; and
a frame portion located at edges of the plate portion and protrudes towards the substrate,
wherein a surface of the plate portion facing the semiconductor package is higher than the first cavity and lower than the second cavity.

3. The semiconductor device of claim 1, wherein the second cavity has a curved surface or an inclined surface.

4. The semiconductor device of claim 1, wherein a maximum width of the first portion is W1, a width of the second portion is W2, a maximum width of the thermal conductive bonding layer in the second cavity is WT, and W2<W1≤WT.

5. The semiconductor device of claim 1, wherein a depth of the second cavity is D, a height of the thermal conductive bonding layer in the second cavity is H, and 0<H≤D.

6. The semiconductor device of claim 1, wherein the semiconductor package comprises an encapsulant, and the second cavity is overlapped with the encapsulant.

7. The semiconductor device of claim 6, wherein the semiconductor package further comprises a plurality of semiconductor dies laterally wrapped by the encapsulant, and the second cavity is overlapped with the encapsulant between two adjacent semiconductor dies among the plurality of semiconductor dies.

8. The semiconductor device of claim 7, wherein a width of the first portion is W1, a width of the second portion is W2, a width of the encapsulant between the two adjacent semiconductor dies is W3, and W2<W1≤W3.

9. A semiconductor device, comprising:
a substrate;
a semiconductor package disposed on the substrate, wherein the semiconductor package comprises at least one semiconductor die and an encapsulant laterally wrapping the at least one semiconductor die;
a thermal conductive bonding layer disposed on the semiconductor package; and
a lid attached to the semiconductor package via the thermal conductive bonding layer,
wherein the lid has a first cavity and a second cavity connected to the first cavity, the semiconductor package is in the first cavity, and the thermal conductive bonding layer is partially in the second cavity, and
wherein an orthogonal projection of the second cavity on the semiconductor package is overlapped with the encapsulant beside the at least one semiconductor die.

10. The semiconductor device of claim 9, wherein the second cavity is located over the encapsulant along a periphery of the semiconductor package.

11. The semiconductor device of claim 9, wherein the at least one semiconductor die includes a first die and a second die, and the orthogonal projection of the second cavity on the semiconductor package is located on the encapsulant between the first die and the second die.

12. The semiconductor device of claim 9, further comprising:
a backside metal layer disposed between the thermal conductive bonding layer and the semiconductor package.

13. The semiconductor device of claim 9, wherein a width of the backside metal layer is smaller than a width of the thermal conductive bonding layer.

14. The semiconductor device of claim 9, wherein the lid comprises:
a plate portion; and
a frame portion located at edges of the plate portion and protrudes towards the substrate,
wherein a surface of the plate portion facing the semiconductor package is higher than the first cavity and lower than the second cavity.

15. The semiconductor device of claim 14, further comprising:
a bonding layer disposed between the substrate and the frame portion or between the substrate and the plate portion.

16. The semiconductor device of claim 14, further comprising:
a passive component disposed between the frame portion and the semiconductor package.

17. A method for manufacturing a semiconductor device, comprising:
disposing a semiconductor package on a substrate; and
attaching a lid to the semiconductor package via a thermal conductive bonding layer,
wherein the lid has a first cavity and a second cavity connected to the first cavity, the semiconductor package is located in the first cavity, and the thermal conductive bonding layer is partially disposed in the second cavity, and
wherein the second cavity has a first portion and a second portion joined with the first portion and narrower than the first portion, the second portion is located between the first portion and the first cavity, and the thermal conductive bonding layer is formed in the second portion.

18. The method for manufacturing the semiconductor device of claim 17, further comprising:
attaching the lid to the substrate through a bonding layer.

19. The method for manufacturing the semiconductor device of claim 18, wherein the lid comprises:
a plate portion; and
a frame portion located at edges of the plate portion and protrudes towards the substrate,
wherein the plate portion is attached to the substrate through the bonding layer.

20. The method for manufacturing the semiconductor device of claim 19, further comprising:
disposing a passive component between the frame portion and the bonding layer.
